(19) United States
(12) Patent Application Publication
(10) Pub. No.: US 2017/0102619 A1
(43) Pub. Date: Apr. 13, 2017

(54) COMPOSITION FOR COATING PHOTORESIST PATTERN AND METHOD FOR FORMING FINE PATTERN USING THE SAME

(71) Applicant: SK hynix Inc., Gyeonggi-do (KR)

(72) Inventors: Sung Jae LEE, Gyeonggi-do (KR); Keun Kyu KONG, Seoul (KR); Jae Hee SIM, Chungcheongbuk-do (KR); Jeong Hoon AN, Gyeonggi-do (KR); Yun Seop OH, Gyeonggi-do (KR)

(21) Appl. No.: 15/058,816

(22) Filed: Mar. 2, 2016

(30) Foreign Application Priority Data
Oct. 12, 2015 (KR) 10-2015-0142360

(51) Int. Cl. G03F 7/40; H01L 21/324; G03F 7/00; H01L 21/027; G03F 7/16; G03F 7/32

(52) U.S. Cl. CPC G03F 7/405; G03F 7/16; G03F 7/40; G03F 7/32; G03F 7/0035; H01L 21/0274; H01L 21/324

(57) ABSTRACT

Disclosed are a composition for coating a photoresist pattern and a method for forming a fine pattern using the same. The composition for coating a photoresist pattern includes a polymer compound containing a hydroxyl group and an ammonium base, and a solvent The method for forming a fine pattern includes coating the composition on a previously formed photoresist pattern to thereby effectively reduce the size of a photoresist contact hole or space, and can be used in all semiconductor processes in which a fine pattern is required to be formed.

### CROSS-REFERENCES TO RELATED APPLICATION

The present application claims priority under 35 U.S.C. §119(a) to Korean application number 10-2015-0142360, filed on Oct. 12, 2015, which is herein incorporated by reference in its entirety.

### BACKGROUND

1. Technical Field

Various embodiments generally relate to a composition for coating a photoresist pattern and a method for forming a fine pattern using the same, and more particularly, to a composition for coating a photoresist pattern, which includes a polymer compound and a solvents The polymer compound contains a hydroxyl group and an ammonium base. The method for forming a fine pattern includes coating the composition on a previously formed photoresist pattern to effectively reduce the size of a photoresist contact hole or space. The composition can be used in all semiconductor processes in which a fine pattern is required to be formed.

2. Related Art

In recent years, as technology for fabricating semiconductor devices has been developed and the fields of application of memory devices have been expanded, the development of lithography processes that is, the development of photoresist materials, new light sources, and light exposure systems, has been accelerated in order to develop memory devices having increased integration density. However, since a resolution obtainable by use of KrF and ArF exposure systems which are currently commonly used is limited to about 0.1 μm, it is difficult to form a pattern smaller than this limit in order to fabricate a highly integrated semiconductor device.

Accordingly, various embodiments according to the present invention are novel and capable of overcoming the resolution limit of conventional photoresist patterns and forming a fine pattern without using expensive materials and complex process steps.

### SUMMARY

Various embodiments are directed to a composition for coating a photoresist pattern hereinafter also referred to as the “photoresist pattern coating composition”, which includes: a polymer compound containing as end groups a hydroxyl group and an ammonium base, which are capable of cross-linking with a photoresist material to form a coating layer on the surface of the photoresist material; and a solvent.

Other embodiments are directed to a method for forming a fine pattern, which includes coating the photoresist pattern coating composition on a previously formed photoresist pattern to thereby effectively reduce the size of a photoresist contact hole or space, and which is applicable to all devices in which a fine pattern is required to be formed.

In an embodiment, A composition for coating a photoresist pattern, comprising: a polymer compound and a solvent, wherein the polymer compound is represented by the following formula 1.

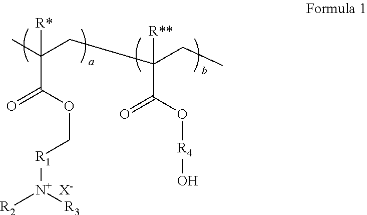

R* and R** are each a hydrogen or a methyl group, wherein R₁ is a linear or branched hydrocarbon group having 1 to 18 carbon atoms, an ether group containing a linear or branched hydrocarbon group having 1 to 18 carbon atoms, or a cyclic hydrocarbon group having 3 to 18 carbon atoms,
wherein R₂ to R₄ are each independently a linear or branched hydrocarbon group having 1 to 18 carbon atoms, or a cyclic hydrocarbon group having 3 to 18 carbon atoms,
wherein is a group capable of forming an ammonium salt, and wherein the molar ratio of a:b ranges from 10:90 to 90:10.

The N⁺X⁻ is NH+Cl⁻, NH⁺I⁻, NH⁺HSO₄⁻, (NH⁺)COO⁻, (NH⁺)SO₃⁻, (NH⁺)SO₄⁻, (NH⁺)PO₃⁻, or (NH⁺)PO₄⁻.

The polymer compound includes a compound represented by the following formulas 1a to 1h or a combination thereof.

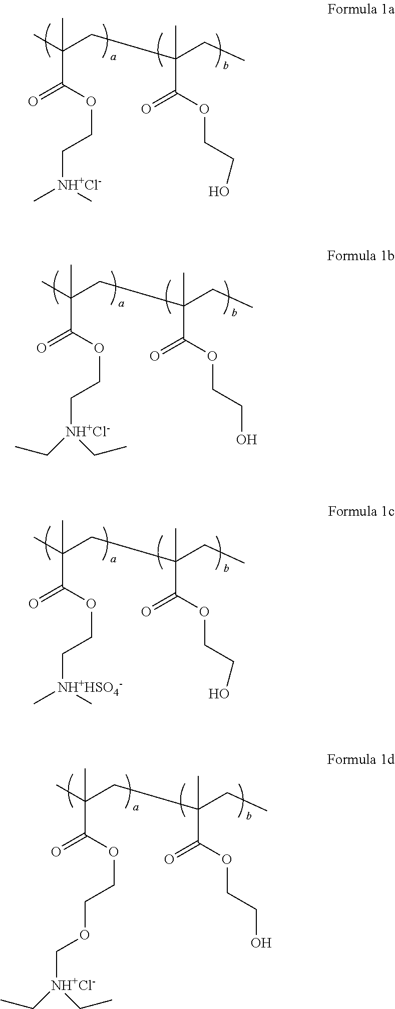

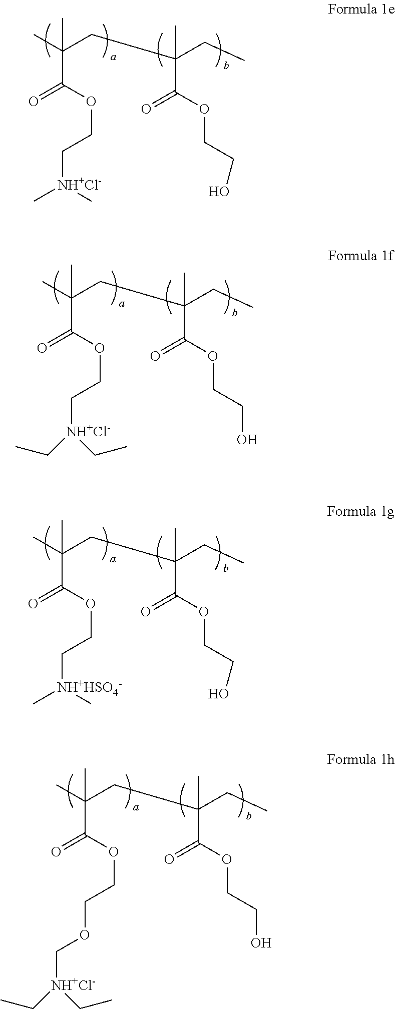

The polymer compound represented by formula 1 is contained in an amount of 0.1-3 wt % based on the total weight of the composition.

The solvent includes alcohol, and wherein the composition further includes a surfactant.

The alcohol is selected from the group consisting of C₁-C₁₀ alkylalcohol, C₂-C₁₀ alkoxy alkylalcohol, or a combination thereof.

The C₁-C₁₀ alkylalcohol is selected from the group consisting of methanol, ethanol, propanol, isopropanol, n-butanol, sec-butanol, t-butanol, 1-pentanol, 2-pentanol, 3-pentanol, 2,2-dimethyl-1-propanol, and a combination thereof.

The C₂-C₁₀ alkoxy alkylalcohol is selected from the group consisting of 2-methoxyethanol, 2-(2-methoxyethoxy)ethanol, 1-methoxy-2-propanol, 3-methoxy-1,2-propanoldiol, and a combination thereof.

The surfactant is contained in an amount of 0.001-0.1 wt % based on the total weight of the composition.

A method for forming a fine pattern, comprising:
a) forming a first photoresist pattern over an underlying layer;
b) coating the composition of claim 1 on the first photoresist pattern to form a composition layer;
c) baking the photoresist pattern coated with the composition layer to form a coating layer at an interface between the photoresist pattern and the composition; and
d) removing an unreacted portion of the composition layer to form a second photoresist pattern.

The baking is performed at a temperature ranging from 100° C. to 200° C.

The removing of the unreacted portion of the composition layer is performed using water or an alkaline developer.

The first photoresist pattern has a first width, and wherein the first width is 30-300 nm.

The second photoresist pattern has a second width, and wherein the second width is 10-40% greater than the first width.

The coating layer has a thickness of 300-3000 Å.

The coating layer has a third width, and wherein the third width is 5-20% of the first width.

A semiconductor device comprising: a photoresist pattern formed over a substrate; and a coating layer formed over the photoresist pattern, wherein the photoresist pattern includes a photoresist material, and wherein the coating layer includes a cross-linking material between the photoresist material and the composition represented by the following formula 1.

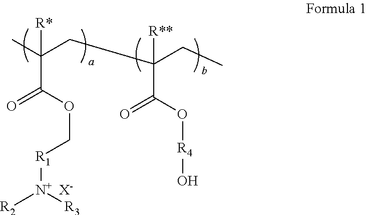

### BRIEF DESCRIPTION OF THE DRAWINGS

FIGS. 1 to 3 are schematic process views illustrating a method for forming a fine pattern using a composition of an embodiment.

FIG. 4 is photograph of a first contact hole pattern obtained before application of a coating composition according to an embodiment.

FIG. 5 is a photograph of a second contact hole pattern obtained after application of a coating composition according to an embodiment.

### DETAILED DESCRIPTION

Hereinafter, a composition for coating a photoresist pattern and a method for forming a photoresist pattern using the same will be described with reference to the accompanying drawings through various examples of embodiments.

The terms and words used in the specification and claims should not be interpreted as being limited to typical meanings or dictionary definitions, but should be interpreted as having meanings and concepts relevant to the technical scope of the embodiments disclosed in the specification.

In an embodiment, a composition for coating a, photoresist pattern includes: a polymer compound represented by the following formula 1; and a solvent.

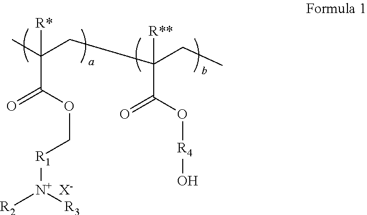

Each of R* and R** is independently a hydrogen or a methyl group; R₁ is a linear or branched hydrocarbon group having 1 to 18 carbon atoms, an ether group containing a linear or branched hydrocarbon group having 1 to 18 carbon atoms, or a cyclic hydrocarbon group having 3 to 18 carbon atoms; each of R₂ to R₄ is independently a linear or branched hydrocarbon group having 1 to 18 carbon atoms or a cyclic hydrocarbon group having 3 to 18 carbon atoms.

N⁺X⁻ is an ammonium salt.

The molar ratio of a:b ranges from 10:90 to 90:10, preferably from 30:70 to 70:30.

Specifically, N⁺X⁻ is NH⁺Cl⁻, NH⁺I⁻, NH⁺HSO₄⁻, (NH⁺)COO⁻, (NH⁺)SO₃⁻, (NH⁺)SO₄⁻, (NH⁺)PO₃⁻, or (NH⁺)PO₄⁻.

The polymer compound represented by formula 1 includes compounds represented by the following formulas 1a to 1h.

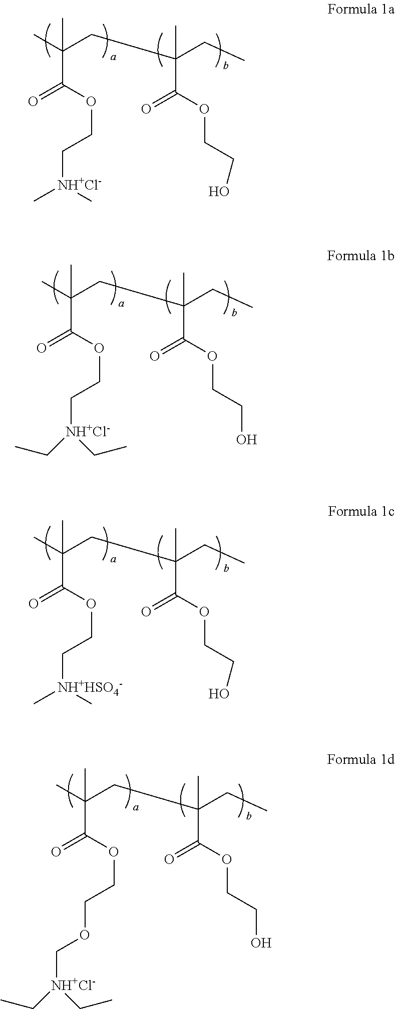

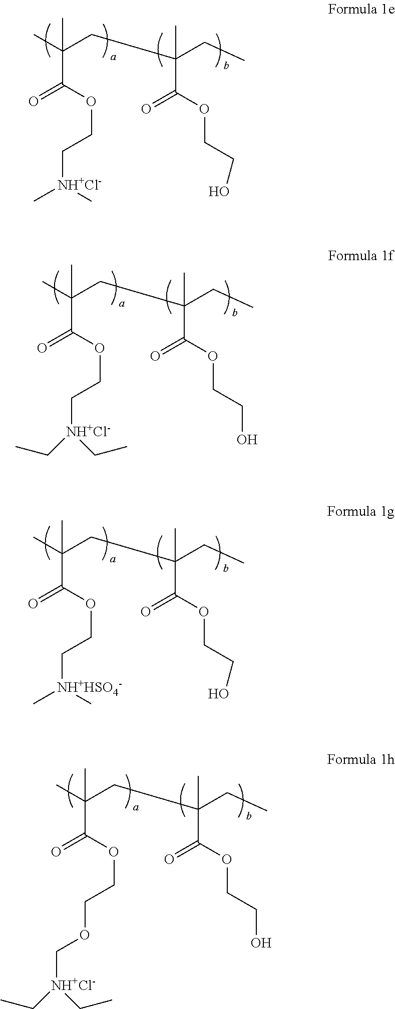

According to the embodiment, the hydroxyl group and ammonium base contained in the polymer compound can react with an underlying photoresist material to form a cross-linking material in a subsequent baking process. That is, the cross-linking material is obtained by cross-linking between the photoresist material and the compound represented the formula 1. The photoresist material forms an underlying photoresist pattern.

For example, an esterification reaction between the end, hydroxyl group of the polymer compound and the carboxylic acid of the photoresist material occurs in the presence of an acid catalyst. The acid catalyst is generated from a photoacid generator included in the underlying photoresist pattern. The esterification reaction occurs during the baking process. See reaction scheme 1 below. Due to the cross-linking reaction, a thin layer, which is also referred to as a coating layer, is formed on the surface of the underlying photoresist material. When the coating layer is formed, the size of the photoresist pattern increases and a space or a distance between two neighboring photoresist patterns decreases. For example, when a hole is present between two neighboring photoresist patterns, the size of the hole is reduced upon formation of the coating layer.

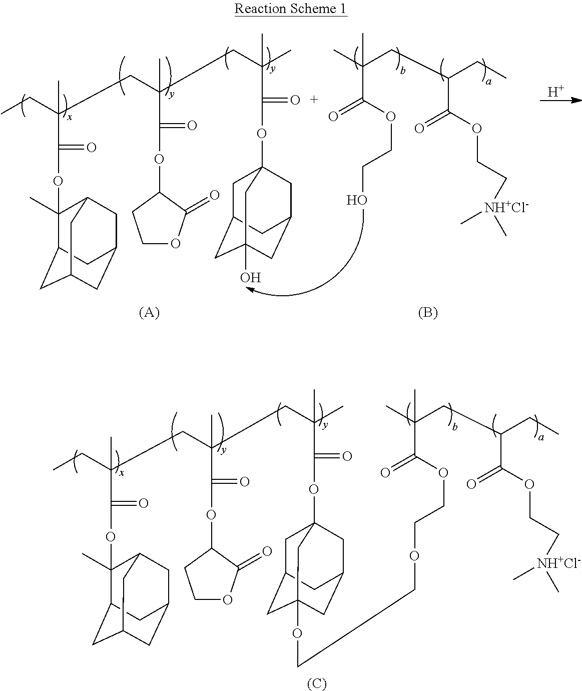

Here, (A) denotes the underlying photoresist material and (B) denotes the compound represented by the formula 1a. Furthermore, water solubility of the photoresist pattern coating composition according to the embodiment is increased by the tertiary ammonium base contained in the polymer compound, and thus defects on the photoresist pattern surface which may occur when developing and removing the photoresist pattern coating composition can be minimized.

A compound, which is not cross-linked with the photosensitive polymer during the baking process, can be easily removed by an alkaline developer in a subsequent removal process. Herein, the amount of polymer attached to the photoresist pattern surface can be controlled by controlling the time and temperature of the baking process.

According to this embodiment, the photoresist pattern size, which reached the limit of conventional exposure processes and photoresist materials can increase using the photoresist pattern coating composition of the embodiment, thereby reducing a distance between two neighboring photoresist patterns. The distance between two neighboring photoresist patterns defines a hole pattern. Thus, a hole pattern with a pattern size smaller than a limit allowed in a given lithography device is formed. As a result, an integration degree of a device can improve.

In the photoresist pattern coating composition according to the embodiment, the content of the polymer compound represented by formula 1 may be 0.1-3 wt % based on the total weight of the photoresist pattern coating composition. If the content of the polymer compound is less than 0.1 wt % it will be difficult to form a coating layer on the surface of the photoresist pattern, and if the content of the polymer compound is more than 3 wt %, the uniformity of the coating layer will be poor.

In the photoresist pattern coating composition according to the embodiment, the solvent may include an alcohol compound. The photoresist pattern coating composition may further include a surfactant.

Herein, the alcohol compound may include a C₁-C₁₀ alkylalcohol, a C₂-C₁₀ alkoxy alkylalcohol, or a mixture thereof. Specifically, the C₁-C₁₀ alkylalcohol may include methanol, ethanol, propanol, isopropanol, n-butanol, sec-butanol, t-butanol, 1-pentanol, 2-pentanol, 3-pentanol, 2,2-dimethyl-1-propanol, or a mixture thereof.

Furthermore, the C₂-C₁₀ alkoxy alkylalcohol may include 2-methoxyethanol, 2-(2-methoxyethoxy)ethanol, 1-methoxy-2-propanol, 3-methoxy-1,2-propanoldiol, or a mixture thereof.

The surfactant serves to increase the coating property of the coating composition to thereby provide a uniform coating surface. The surfactant that is used in the embodiment may be a conventional surfactant. For example, an anionic surfactant, a cationic surfactant, or an amphoteric surfactant may be used alone or in a mixture depending on the size and thickness of the photoresist pattern. More specific examples of the surfactant include alkylbenzene sulfonate surfactants, higher amine halides, quaternary ammonium surfactants, alkyl pyridinium surfactants, amino acid surfactants, sulfonimide surfactants, and the like.

The content of the surfactant is preferably 0.001-0.1 wt % based on the total weight of the photoresist pattern coating composition.

In addition, the photoresist pattern coating composition according to the embodiment may further include additives such as an acid catalyst, a surfactant, a basic compound and the like order to improve resolution and coating properties.

The acid catalyst serves to increase the crosslinking density or rate during formation of the coating layer. For example, the acid catalyst that is used in the embodiment may be hydrochloric acid, sulfuric acid, phosphoric acid, methylsulfonic acid, ethylsulfonic acid, propylsulfonic acid, butylsulfonic acid, benzenesulfonic acid, 2,4-dimethylbenzenesulfonic acid, p-toluenesulfonic acid (PTSA), camphorsulfonic acid, naphthylsulfonic acid, cyclohexylsulonic acid, acetic add, ethylacetic acid, propylacetic add, isopropylacetic acid, or mixtures thereof.

The surfactant serves to increase the coating property of the coating composition to thereby provide a uniform coating surfaces. The surfactant that is used in the embodiment may be a conventional surfactant. For example, an anionic surfactant, a cationic surfactant or an amphoteric surfactant may be used alone or in a mixture depending on the size and thickness of the photoresist pattern. More specific examples of the surfactant include alkylbenzene sulfonate surfactants, higher amine halides, quaternary ammonium surfactants, alkyl pyridinium surfactants, amino acid surfactants, sulfonimide surfactants, and the like.

In addition, the basic compound that is used in the embodiment serves as a crosslinker and a stabilizer and may be a conventional amine compound. For example, the basic compound may be triethanolamine (TEOA), 2-aminoethanol, 2-(2-aminoethoxy)ethanol, or the like.

The content of the additives is preferably 0.001-0.1 wt % based on the total weight of the pattern coating composition. If the content of the additives is less than 0.001 wt %, the effect of the additives will be insufficient. Thus, the quality of the coating layer becomes poor, or the effect of increasing the rate of crosslinking in the coating layer cannot be obtained. If the content of the additives is more than 0.1 wt %, the quality of the coating layer becomes poor, or an excessive loss of the photoresist pattern can occur during formation of the coating layer to thereby deteriorate the surface of the photoresist pattern.

Furthermore, the photoresist pattern coating composition according to the embodiment has the following properties, and thus can effectively reduce the size of a space or hole. The space or the hole is defined by the photoresist pattern and is obtained by forming a uniform coating layer on the photoresist pattern: (1) the photoresist pattern coating composition does not damage a photoresist material and/or an underlying layer pattern. The photoresist pattern coating composition can form a uniform coating layer when it is coated on an underlying photoresist pattern by a spin-coating technique; (2) the photoresist pattern coating composition has excellent adhesion properties so as to form a thin layer on the surface of the photoresist pattern when the coating composition is applied; (3) the photoresist pattern coating composition has etching resistance similar to or higher than that of conventional photoresist materials; (4) the photoresist pattern coating composition does not form foams on the surface of the photoresist pattern when it is applied; and (5) the photoresist pattern coating composition has an almost vertical profile (80-100°) after it is applied.

In another embodiment, there is provided a method for forming a fine pattern, the method including: a) forming a first photoresist pattern on a semiconductor substrate; b) coating the photoresist pattern coating composition of the embodiment on the formed first photoresist pattern; c) baking the photoresist pattern having the photoresist pattern coating composition coated thereon, thereby forming a coating layer at the interface between the photoresist pattern and the photoresist pattern coating composition, and d) removing an unreacted portion of the photoresist pattern coating composition, which does not form the coating layer, thereby forming a second photoresist pattern including the coating layer formed on the first photoresist pattern.

Herein, the baking step is preferably performed at a temperature of 100 to 200° C., particularly 160° C. or lower, more particularly 100 to 150° C., for 30 seconds to 1 minute. That is, the amount of polymer attached to the photoresist pattern surface can be controlled depending on the baking temperature. If the baking temperature is lower than 100° C., the effect of coating the composition will be insufficient, and if the baking temperature is higher than 200° C., the polymer will be excessively attached to plug a space between two neighboring photoresist patterns.

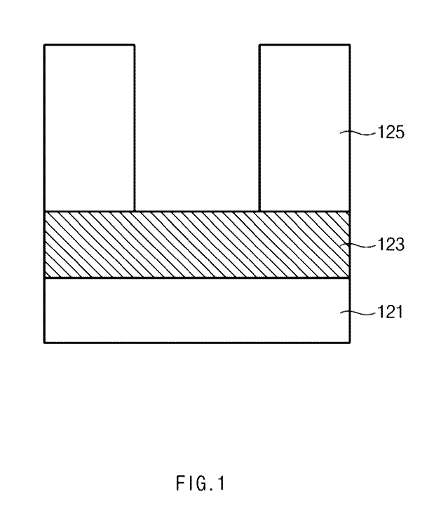

Hereinafter, embodiments will be described in detail with reference to the accompanying drawings. FIGS. 1 to 3 are schematic process views illustrating a method for forming a fine pattern using the pattern coating composition according to the embodiment.

Referring to FIG. 1, a layer 123 and a photoresist layer (not shown) are sequentially formed on a semiconductor substrate 121. The photoresist layer (not shown) is subjected to exposure and development processes, thereby forming a first photoresist pattern 125.

Herein, the material that is used to form the photoresist layer is not specifically limited. A conventional positive photoresist material or negative photoresist material may be employed. Specifically, a positive photoresist material is preferably used to form the photoresist layer.

The exposure process is preferably performed with exposure energy of 0.1-100 mJ/cm° using KrF (248 nm), ArF (193 nm), VUV (157 nm), EUV (13 nm), E-beams, X-rays or ion beams as a light source.

In addition, the method may further include performing a soft baking process before the exposure process and performing a post baking process after the exposure process. The baking process is preferably performed at a temperature ranging from 70° C. to 200° C. The development process is performed using an alkaline developer such as an aqueous solution containing 0.01-5 wt % of tetramethylammonium hydroxide (TMAH) The line width (CD) of the first photoresist pattern obtained by the development process is preferably 30-300 nm, particularly 50 to 250 nm.

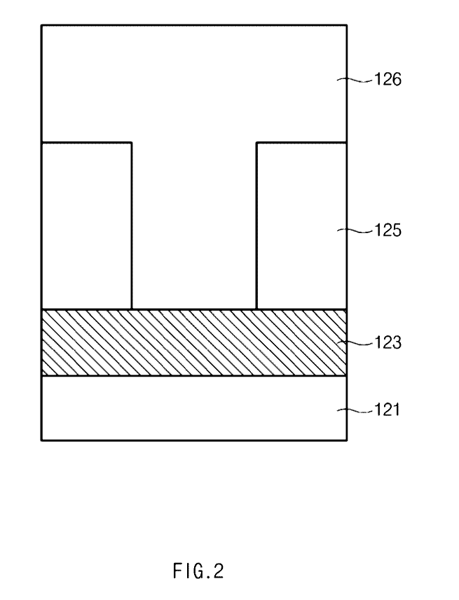

Next, referring to FIG. 2, the photoresist pattern coating composition as described above may be coated on the first photoresist pattern 125 by a spin-coating technique, thereby forming a photoresist pattern coating composition layer 126. Herein, the photoresist pattern coating composition can be prepared by adding the compound of formula 1 and optionally additives to a solvent and filtering the mixture through a 0.2-μm filter.

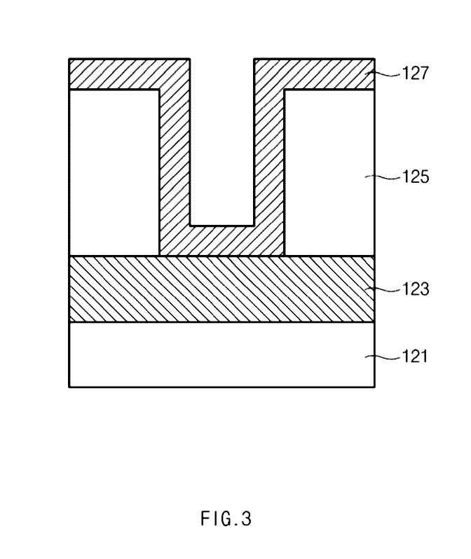

Next, referring to FIG. 3, the photoresist pattern having the photoresist pattern coating composition coated thereon is baked, thereby forming a coating layer 127 at the interface between the photoresist pattern and the photoresist pattern coating composition.

During the baking process, the thickness, size or the like of the coating layer can further be controlled by suitably controlling the baking temperature and time. Herein, the baking step is preferably performed at a temperature of 160° C. or lower, particularly 100° C. to 250° C., for 30 seconds to 1 minute.

Next, an unreacted portion of the photoresist pattern coating composition, which was not cross-liked with the photosensitive polymer on the photoresist pattern surface, may be removed using a developer.

In addition, the removal of the photoresist pattern coating composition may be performed using water, a basic or alkaline developer.

As a result, according to the disclosed embodiment, a space or a distance between two neighboring photoresist patterns can be effectively reduced using the photoresist pattern coating composition of the embodiment, for example, a pattern shrink material, thus increasing the integration density of circuits.

According to the method of the embodiment, the second photoresist pattern having a line width (CD) that is about 0-40% greater than the line width (CD) of the first photoresist pattern can be formed. For example, when the ratio of a line width (CD) to a space width of the first photoresist pattern is 1:1, the ratio of a line width (CD) to a space width of the second photoresist pattern is preferably 1: 0.6-09. In addition, the thickness of the coating layer is preferably 30-3000 Å, particularly 1500 Å. The coating layer has a third width, and wherein the third width is 5-20% of the first width.

In still another embodiment, a device includes a substrate and a photoresist pattern formed on the substrate. The photoresist pattern is formed by the fine pattern forming method of the disclosed embodiment. The photoresist pattern has a coating layer. The coating layer contains the ammonium base-containing polymer compound as described above.

Hereinafter, examples will be described in detail. However, these examples are merely for illustrative purposes and are not intended to be restrictive.

### EXAMPLES

I. Preparation of Photoresist Pattern Coating Polymer

### Preparation Example 1

13.0 g (0.1 mol) of a monomer of the following formula 2, 19.4 g (0.1 mol) of a monomer of the following formula 3, and 0.7 g of azobis(isobutyronitrile) (AIBN) were placed in a reactor. The reaction materials were dissolved in 100 g of acetonitrile, and then polymerized at 70° C. for 24 hours. After completion of the polymerization reaction, the reaction product was slowly added dropwise to an excessive amount of diethyl ether and was precipitated therein, after which it was dissolved in acetonitrile. The dissolved product was precipitated again in diethyl ether, thereby preparing a polymer represented by formula 1a. The weight-average molecular weight (Mw) and polydispersity (PD) of the synthesized polymer were measured using GPC (gel permeation chromatography) (GPC analysis: Mw=3,600, and PD=1.95).

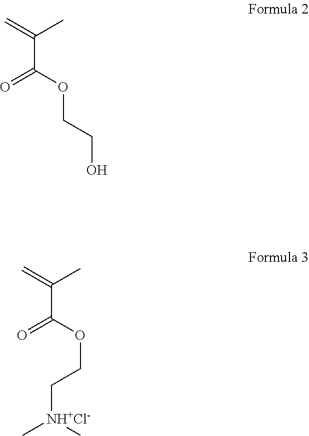

### Preparation Example 2

A polymer represented by formula 1c was prepared in the same manner as described In Preparation Example 1, except that 25.5 g (0.1 mol) of a monomer of the following formula 4 was used instead of the monomer of formula 3. The weight-average molecular weight (Mw) and polydispersity (PD) of the synthesized polymer were measured using GPC (gel permeation chromatography) (GPC analysis: Mw=4,800, and PD=2.01).

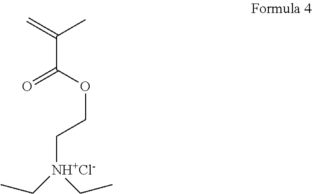

### Preparation Example 3

A polymer represented by formula 1e was prepared in the is same manner as described in Preparation Example 1, except that 11.6 g (0.1 mol) of a monomer of the following formula 5 was used instead of the monomer of formula 2. The weight-average molecular weight (Mw) and polydispersity (PD) of the synthesized polymer were measured using GPC (gel permeation chromatography) (GPC analysis: Mw=5400, and PD=2.11).

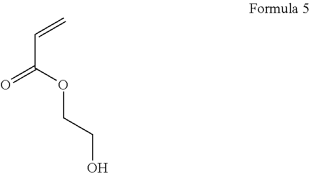

### Preparation Example 4

A polymer represented by formula 1f was prepared in the same manner as described in Preparation Example 2, except that 38.6 g (0.1 mol) of a monomer of the following formula 6 was used instead of the monomer of formula 2. The weight-average molecular weight (M)and polydispersity (PD) of the synthesized polymer were measured using GPC (gel permeation chromatography) (GPC analysis: Mw=3,700, and PD=1.99).

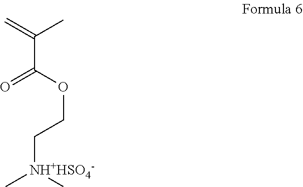

II. Preparation of Photoresist Pattern Coating Composition

### Examples 1-1 to 1-4

As shown in Table 1 below, 2.7 g of the photoresist pattern coating polymers synthesized in Preparation Examples 1 to 4, and 0.3 g of a water-soluble surfactant (a sulfonamide-based surfactant, TCI) were completely dissolved in 17.0 g of deionized water or 17.0 g of a 6:4 mixture of deionized water and isopropanol, and the solution was filtered through a 0.2-μm disc filter, thereby preparing photoresist pattern coating compositions.

TABLE 1

| | | Amount | | Deionized | |
|---|---|---|---|---|---|
| | Polymer | used | Surfactant | water | Alcohol |
| Example 1-1 | Polymer 1a | 2.7 g | 0.3 g | 17.0 g | |
| Example 1-2 | Polymer 1c | 2.7 g | 0.3 g | 17.0 g | |
| Example 1-3 | Polymer 1e | 2.7 g | 0.3 g | 17.0 g | |
| Example 1-4 | Polymer 1f | 2.7 g | 0.3 g | 10.2 g | 6.8 g |

III. Method for Formation of Fine Pattern for Semiconductor Device

Step 1

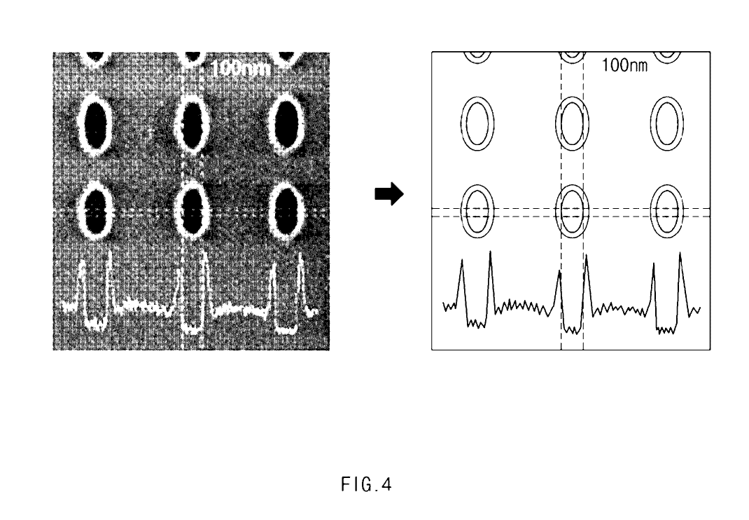

2 g of an ArF photoresist polymer (molecular weight (Mw): 10,100; polydispersity (PD): 1.89; x: y: z (mole %)=45: 40: 15) represented by the following formula 7, 0.02 g of triphenylsulfonium triflate and 0.01 g of triethanolamine were dissolved in 10 g of propylene glycol monomethyl ether acetate (PGMEA) to form a solution. The solution was filtered through a 0.2-μm filter, thereby preparing a photoresist composition. A wafer with a first contact hole pattern is prepared. The first contact hole pattern has a size of 100 nm. See FIG. 4.

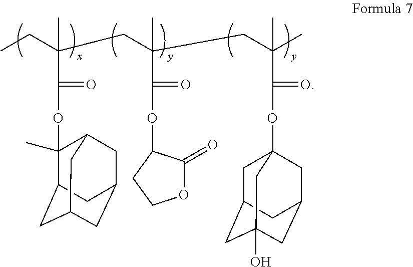

Step 2

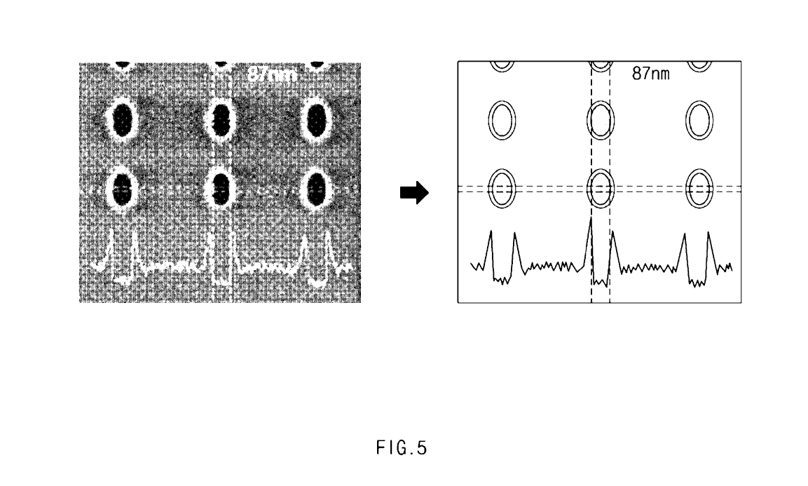

Thereafter, on each of wafers having the first photoresist pattern, each of the photoresist pattern coating compositions prepared in Examples 1-1 to 1-4 was spin-coated to form a thin layer, followed by soft baking in an oven or on a hot plate at 150° C. for 60 seconds. Then, each of the wafers was dipped in deionized water or an aqueous solution containing 2.38 wt % of tetramethylammonium hydroxide (TMAH) for 60 seconds to develop the first photoresist contact hole pattern, thereby forming a second photoresist contact hole pattern. See FIG. 5. The change in size (critical dimension (CD)) of the second photoresist pattern is shown in Table 2 below.

TABLE 2

| | | CD of first PR | CD of second PR |
|---|---|---|---|
| Classification | | pattern | pattern |
| First photoresist | — | 100 nm | — |
| pattern | | | |
| — | Example 1-1 | — | 83 nm |
| — | Example 1-2 | — | 87 nm |
| — | Example 1-3 | — | 86 nm |
| — | Example 1-4 | — | 81 nm |

IV. Measurement of a Thickness of Coating Layer Depending on Various Baking Temperatures

Step 1

2 g of an ArF photoresist polymer (molecular weight (Mw): 10,100; polydispersity (PD): 1.89; a: b: c (mole %)=45: 40: 15) represented by the above formula 7, 0.02 g of triphenylsulfonium triflate and 0.01 g of triethanolamine were dissolved in 10 g of propylene glycol monomethyl ether acetate (PGMEA), and the solution was filtered through a 0.2-μm filter, thereby preparing a photoresist composition. A first contact hole pattern having a size of 100 nm was prepared.

Step 2

Thereafter, on the wafer having the first photoresist pattern formed thereon, the photoresist pattern coating composition prepared in Examples 1-1 was spin-coated to form a thin layer, followed by soft baking at various temperatures as shown in Table 3 below. Then, each of the wafers was dipped in deionized water or an aqueous solution containing 2.38 wt % of tetramethylammonium hydroxide (TMAH) for 60 seconds to develop the first photoresist contact hole pattern, thereby forming a second photoresist pattern. The change in the contact hole pattern size (CD) of the second photoresist pattern depending on a change in the baking temperature is shown in Table 3 below.

TABLE 3

| | CD of first PR | CD of | |
|---|---|---|---|
| | contact hole | second PR | Thickness of the |
| | pattern | pattern | coating layer |
| 120° C. | 100 nm | 97 nm | 3 |
| 130° C. | | 90 nm | 10 |
| 140° C. | | 86 nm | 14 |
| 150° C. | | 83 nm | 17 |
| 160° C. | | 76 nm | 24 |
| 170° C. | | 67 nm | 33 |

According to the embodiments as described above, a fine photoresist pattern can be formed in a simple manner by coating the formed photoresist pattern with a photoresist pattern coating composition according to an embodiment. Since an unreacted material can be easily removed from the coating layer during development after formation of the coating layer, no additional development process is required. Thus, the disclosed embodiment is cost-effective. This method of the embodiment can be advantageously used in any semiconductor processes to overcome a wavelength limit.

While various embodiments have been described above, it will be understood to those skilled in the art that the embodiments described are by way of example only. Accordingly, the composition and method described herein should not be limited based on the described embodiments.

What is claimed is:

1. A composition for coating a photoresist pattern, comprising: a polymer compound and a solvent,
wherein the polymer compound is represented by the following formula 1: 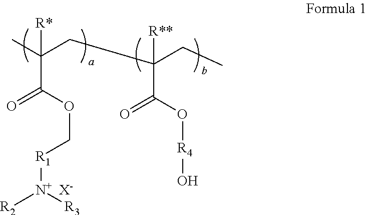
wherein R* and R** are each a hydrogen or a methyl group, wherein R₁ is a linear or branched hydrocarbon group having 1 to 18 w carbon atoms, an ether group containing a linear or branched hydrocarbon group having 1 to 18 carbon atoms, or a cyclic hydrocarbon group having 3 to 18 carbon atoms,
wherein R₂ to R₄ are each independently a linear or branched hydrocarbon group having 1 to 18 carbon atoms, or a cyclic hydrocarbon group having 3 to 18 carbon atoms,
wherein N⁺X⁻ is an ammonium salt, and
wherein the molar ratio of a:b ranges from 10:90 to 90:10.

2. The composition of claim 1, wherein N⁺X⁻ is NH⁺Cl⁻, NH⁺I⁻, NH⁺HSO₄⁻, (NH⁺)COO⁻, (NH⁺)SO₃⁻, (NH⁺)SO₄⁻, (NH⁺)PO₃⁻, or (NH⁺)PO₄⁻.

3. The composition of claim 1, wherein the polymer compound includes a compound represented by the following formulas 1a to 1h or a combination thereof.

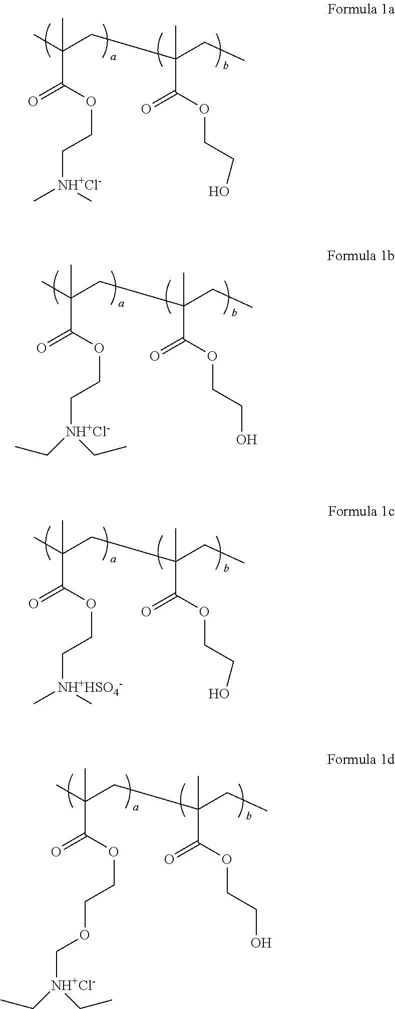

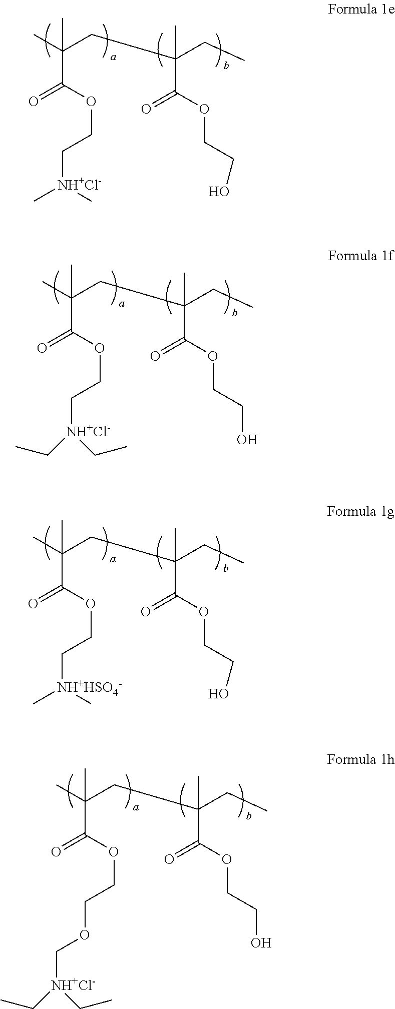

4. The composition of claim 1, wherein the polymer compound represented by formula 1 is contained in an amount of 0.1-3 wt % based on the total weight of the composition.

5. The composition of claim 1, wherein the solvent includes alcohol, and
wherein the composition further includes a surfactant.

6. The composition of claim 5, wherein the alcohol is selected from the group consisting of C₁-C₁₀ alkylalcohol, C₂-C₁₀ alkoxy alkylalcohol, and a combination thereof.

7. The con, position of claim 6, wherein the C₁-C₁₀ alkylalcohol selected from the group consisting of methanol ethanol, propanol, isopropanol, n-butanol, sec-butanol, t-butanol, 1-pentanol, 2-pentanol, 3-pentanol, 2,2-dimethyl-1-propanol, and a combination thereof.

8. The composition of claim 6, wherein the C₂-C₁₀ alkoxy alkylalcohol is selected from the group consisting of 2-methoxyethanol-2-(2-methoxyethoxy)ethanol, 1-methoxy-2-propanol, 3-methoxy-1,2-propanoldiol, and a combination thereof.

9. The composition of claim 5, wherein the surfactant is contained in an amount of 0.001-0.1 wt % based on the total weight of the composition.

10. A method for forming a fine pattern, comprising:
a) forming a first photoresist pattern over an underlying layer;
b) coating the composition of claim 1 on the first photoresist pattern to form a composition layer;
c) baking the photoresist pattern coated with the composition layer to form a coating layer at an interface between the photoresist pattern and the composition; and
d) removing an unreacted portion of the composition layer to form a second photoresist pattern.

11. The method of claim 10, wherein the baking is performed at a temperature ranging from 100° C. to 200° C.

12. The method of claim 10, wherein the removing of the unreacted portion of the composition layer is performed using water or an alkaline developer.

13. The method of claim 10, wherein the first photoresist pattern has a first width, and
wherein the first width is 30-300 nm.

14. The method of claim 13, wherein the second photoresist pattern has a second width, and
wherein the second width is 10-40% greater than the width.

15. The method of claim 10, wherein the coating layer has a thickness of 300-3000 Å.

16. The method of claim 10, wherein the coating layer has a third width, and
wherein the third width is 5-20% of the first width.

17. A semiconductor device comprising:
a photoresist pattern formed over a substrate; and
a coating layer formed over the photoresist pattern,
wherein the photoresist pattern includes a photoresist material, and
wherein the coating layer includes a cross-linking material between the photoresist material and the composition represented by the following formula 1. [chemical structure]
